(19) United States
(12) Patent Application Publication
(10) Pub. No.: US 2024/0071946 A1
(43) Pub. Date: Feb. 29, 2024

(54) Electromagnetic Interference Shield with Thermal Conductivity

(71) Applicant: Apple Inc., Cupertino, CA (US)

(72) Inventors: Murali Krishna Atluru, Liberty Hill, TX (US); Cheng P Tan, Fremont, CA (US)

(21) Appl. No.: 18/169,662

(22) Filed: Feb. 15, 2023

Related U.S. Application Data
(60) Provisional application No. 63/400,651, filed on Aug. 24, 2022.

(51) Int. Cl. H01L 23/552; H01L 23/367

(52) U.S. Cl. CPC H01L 23/552; H01L 23/3675

(57) ABSTRACT

The present disclosure is directed to thermal management and electromagnetic interference (EMI) shielding techniques for a system on a chip (SOC) device to reduce the thermal resistance between a SOC die of the SOC device and heat dissipation components, while still providing EMI shielding to components of the SOC device. For example, a SOC device may include an EMI mesh disposed on the SOC die. The EMI mesh includes a plurality of windows such that a thermal interface material (TIM) may extend through the plurality of windows and physically couple both the heat dissipation components (e.g., a spreader) and the SOC die while still providing EMI shielding to the SOC die.

### CROSS-REFERENCE TO RELATED APPLICATIONS

This application claims priority to U.S. Provisional Application No. 63/400,651, filed Aug. 24, 2022, entitled “ELECTROMAGNETIC INTERFERENCE SHIELD WITH THERMAL CONDUCTIVITY,” the disclosure of which is incorporated by reference herein in its entirety for all purposes.

### BACKGROUND

The present disclosure relates generally to electromagnetic interference shielding and thermal management features for electronic devices.

In electronic devices, a system on a chip integrated circuit (SOC die) may generate heat and electromagnetic radiation when in operation. At least in some instances, electromagnetic radiation may also be generated by a memory component (e.g., a dynamic random-access memory (DRAM)) or other electrical components on the SOC die. The SOC die, the DRAM, and other electrical components may be thermally coupled to one or more heat dissipation components (e.g., a heat sink, heat pipes, and so on) via one or more materials or layers, such as thermal interface materials and a shield lid for electromagnetic interference shielding. However, each of these materials may increase the thermal resistance between the SOC die and the heat dissipation components, thereby reducing the efficiency of heat dissipation of the SOC die, the DRAM, and other electrical components.

### SUMMARY

In one embodiment, an electronic device may include a semiconductor die and a thermal interface material (TIM) thermally coupled to surface of the semiconductor die. The electronic device may include shielding lid thermally coupled to the semiconductor die along the surface of the semiconductor die.

In another embodiment, a thermal electromagnetic interference (EMI) shield may include an EMI mesh having a conductive material forming a plurality of windows. The thermal electromagnetic interference (EMI) shield may also include thermal interface material (TIM) coupled to the conductive material.

In a further embodiment, a thermal management system may include a thermal electromagnetic interference (EMI) shield. The thermal electromagnetic interference (EMI) shield may include a thermal interface material (TIM). The thermal electromagnetic interference (EMI) shield may also include an EMI mesh thermally coupled to the TIM. The EMI mesh may include a plurality of windows. A portion of the TIM is disposed between the plurality of windows. The thermal management system may also include a heat spreader physical coupled to the TIM.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings described below in which like numerals refer to like parts:

FIG. 1 is a block diagram of an electronic device, in accordance with an embodiment of the present disclosure;

FIG. 2 is a perspective view of the electronic device of FIG. 1 in the form of a notebook computer, in accordance with an embodiment of the present disclosure;

FIG. 3 is a front view of the electronic device of FIG. 1 in the form of a handheld device, in accordance with an embodiment of the present disclosure;

FIG. 4 is a front view of the electronic device of FIG. 1 in the form of portable tablet computer, in accordance with an embodiment of the present disclosure;

FIG. 5 is a front view of the electronic device of FIG. 1 in the form of a desktop computer, in accordance with an embodiment of the present disclosure;

FIG. 6 is a front and side view of the electronic device of FIG. 1 in the form of a wearable electronic device, in accordance with an embodiment of the present disclosure;

FIG. 7 is a first cross-sectional perspective view of a system-on-a-chip (SOC) device having a thermal management system with a thermal interface EMI shield subsystem, in accordance with an embodiment of the present disclosure;

FIG. 8 is a second cross-sectional perspective view of the SOC device of FIG. 7, in accordance with an embodiment of the present disclosure;

FIG. 9 is a perspective view of a shield lid that may be used in the thermal management system of FIGS. 7 and 8, in accordance with an embodiment of the present disclosure;

FIG. 10A is a perspective view of a first mesh portion that may be used in the shielding lid of FIG. 9, in accordance with an embodiment of the present disclosure;

FIG. 10B is a perspective view of a second mesh portion that may be used in the shielding lid of FIG. 9, in accordance with an embodiment of the present disclosure; and

FIG. 11 is a flowchart of a method for assembling the thermal management system with the thermal interface EMI shielding subsystem of FIG. 7, in accordance with an embodiment of the present disclosure.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on.

This disclosure is directed to techniques for improving the heat dissipation of system on a chip (SOC) devices while reducing a likelihood of electromagnetic interference (EMI) to the SOC devices. For example, a die of the SOC may be indirectly thermally coupled to one or more heat pipes that transfer heat from the SOC die. As generally described above, the addition of layers and/or materials between the SOC die and heat dissipation components (e.g., a heat sink, heat pipes, and the like) may increase the thermal resistance between the SOC die. For example, a thermal pathway between the SOC die and the one or more heat pipes may include multiple intervening materials, such as a first thermal interface material (TIM), a conductive and/or electromagnetically shielding lid, a second TIM, and a spreader. However, directly coupling the SOC die to the heat spreader may be inefficient due to the rigidity or relative hardness of the materials, which may reduce or minimize the surface area contact between the SOC die and the heat spreader. Moreover, the SOC die should be electromagnetically shielded otherwise electromagnetic signals produced by electronic components around the SOC die may negatively affect operations of the SOC die, and/or electromagnetic signals produced by the SOC die may negatively affect operations of the electronic components. Accordingly, one or more thermal interface materials (TIN/Is) (e.g., the first intervening TIM and the second TIM) may be disposed between the SOC die, an electromagnetic shield, and the heat spreader to improve the thermal conductivity between the two solid materials. For example, the first TIM may be disposed between the SOC die and the conductive lid to facilitate heat transfers from the SOC die to the conductive lid. Moreover, a second TIM may be disposed between the conductive lid and the heat spreader to facilitate heat transfer from the conductive lid to the heat spreader, and ultimately the heat pipes. However, each intervening layer between the SOC die and the heat pipe (e.g., a first TIM layer, the electromagnetic shield, and a second TIM layer) may increase the thermal resistance between the SOC die and the heat pipe, and thus reduces heat dissipation from the SOC die.

As such, embodiments disclosed herein provide various apparatuses and techniques to increase the heat dissipation from the SOC die of the SOC device while still providing EMI shielding to the SOC die. To do so, embodiments disclosed herein include a thermal management system that includes a thermal interface EMI shield. In general, the thermal interface EMI shield includes a thermal interface material (TIM) and an EMI mesh (e.g., a mesh lid or mesh EMI lid) having one or more windows that form a mesh-like, webbed, or net-structured conductive lid that permits a portion of the TIM to permeate, extend, or otherwise traverse the window, thereby enabling the TIM to directly couple to both the SOC die and the heat spreader. In some embodiments, the TIM may include a phase change material, a thermal paste, a thermal adhesive, or other types of TIM known by one of ordinary skill in the art. Additionally, it should be noted that adding additional materials or layers between the SOC die and the heat spreader may increase the thermal resistance. Accordingly, it is presently recognized that it may be advantageous to provide a thermal interface EMI shield that reduces the amount of material (e.g., a thickness of layers) between the SOC die and the heat spreader, while providing EMI shielding of the SOC die and thermally coupling the SOC die to the heat spreader. Accordingly, embodiments disclosed herein provide direct coupling between the SOC die and the heat spreader via a TIM material while still providing electromagnetic interference shielding to the SOC die.

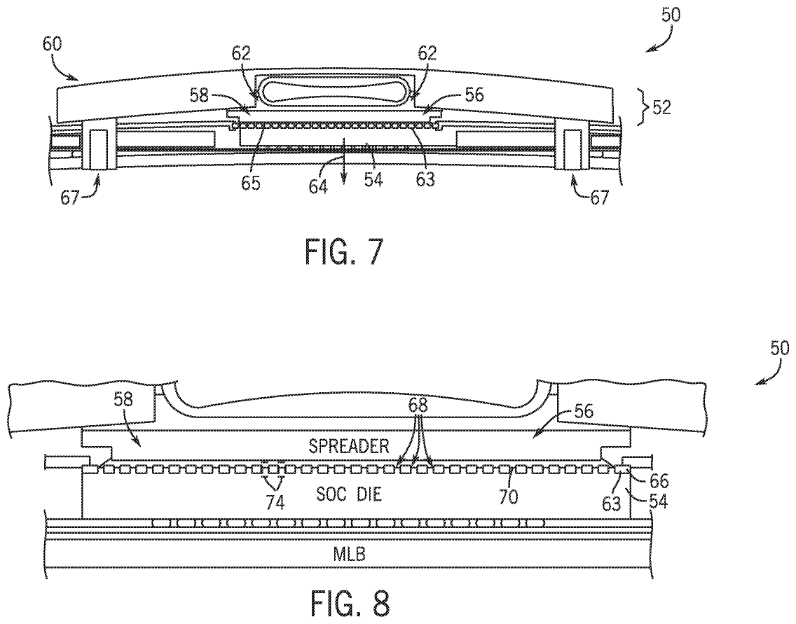

For example, the windows of the mesh lid may permit a TIM having a relatively low viscosity to permeate through the windows (e.g., with gravity acting on the TIM). In some embodiments, the windows may permit a TIM having a relatively high viscosity to permeate through the windows with a suitable pressure applied to the TIM (e.g., the pressure may be applied by the heat spreader and a compression component, as described in more detail with respect to FIG. 7). Furthermore, the windows of the mesh lid are disposed between a conductive material of the mesh lid, and thus, the conductive material may form an EMI barrier over the SOC die. Indeed, the conductive material of the mesh lid itself may also be in direct contact or directly couple to the SOC die and/or the heat spreader.

Accordingly, the disclosed thermal interface EMI shield may facilitate direct physical coupling between the SOC die the TIM or both the TIM and the mesh lid. In this way, the total thickness of the TIM between the SOC die and the heat spreader may be decreased, thereby reducing the thermal resistance between the SOC die and the spreader while also providing electromagnetic interference shielding to the SOC die.

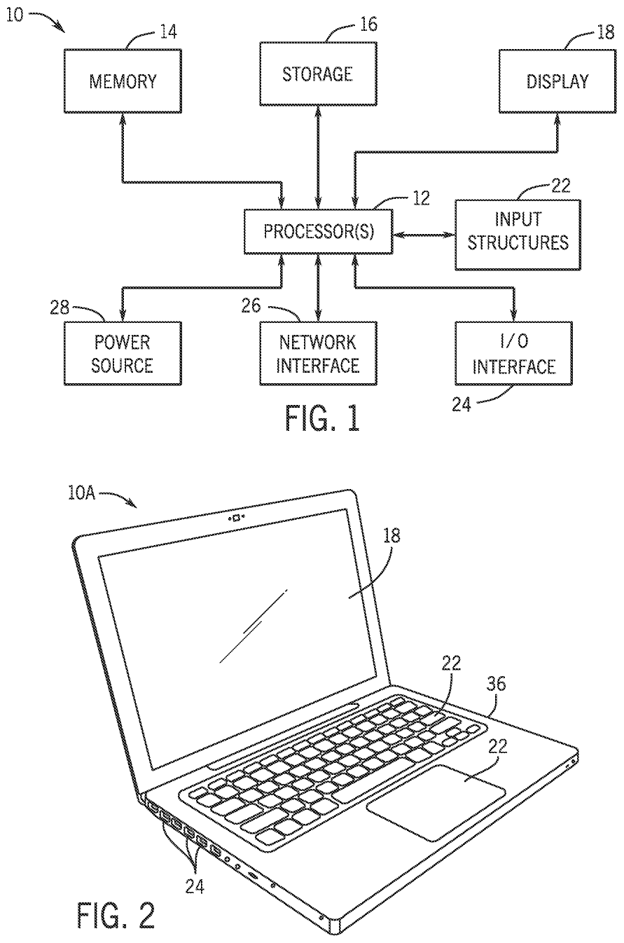

With the foregoing in mind, a general description of suitable electronic devices that may employ the presently disclosed thermal interface EMI shield will be provided below. Turning first to FIG. 1, an electronic device 10 according to an embodiment of the present disclosure may include, among other things, one or more processor(s) 12, memory 14, nonvolatile storage 16, a display 18, input structures 22, an input/output (I/O) interface 24, a network interface 26, and a power source 28. The various functional blocks shown in FIG. 1 may include hardware elements (including circuitry), software elements (including computer code stored on a computer-readable medium) or a combination of both hardware and software elements. It should be noted that FIG. 1 is merely one example of a particular implementation and is intended to illustrate the types of components that may be present in electronic device 10.

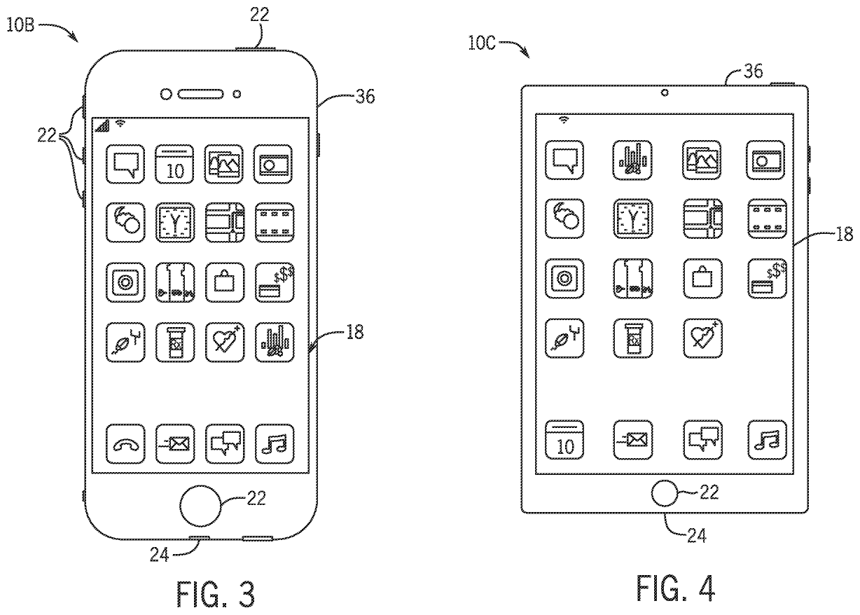

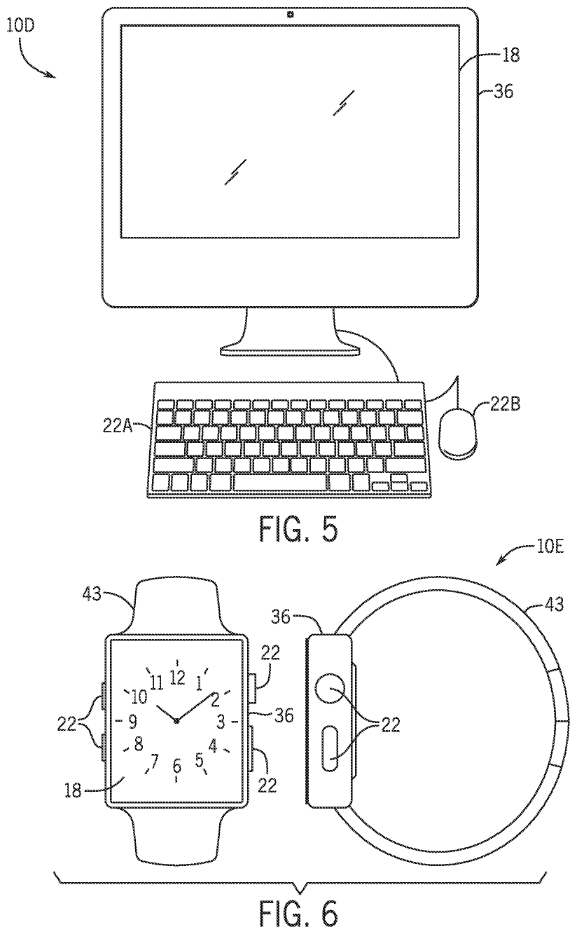

By way of example, the electronic device 10 may represent a block diagram of the notebook computer depicted in FIG. 2, the handheld device depicted in FIG. 3, the handheld device depicted in FIG. 4, the desktop computer depicted in FIG. 5, the wearable electronic device depicted in FIG. 6, or similar devices. It should be noted that the processor(s) 12 and other related items in FIG. 1 may be generally referred to herein as “data processing circuitry.” Such data processing circuitry may be embodied wholly or in part as software, firmware, hardware, or any combination thereof Furthermore, the data processing circuitry may be a single contained processing module or may be incorporated wholly or partially within any of the other elements within the electronic device 10.

In the electronic device 10 of FIG. 1, the processor(s) 12 may be operably coupled with the memory 14 and the nonvolatile storage 16 to perform various algorithms. Such programs or instructions executed by the processor(s) 12 may be stored in any suitable article of manufacture that includes one or more tangible, computer-readable media at least collectively storing the instructions or routines, such as the memory 14 and the nonvolatile storage 16. The memory 14 and the nonvolatile storage 16 may include any suitable articles of manufacture for storing data and executable instructions, such as random-access memory, read-only memory, rewritable flash memory, hard drives, and optical discs. In addition, programs (e.g., an operating system) encoded on such a computer program product may also include instructions that may be executed by the processor(s) 12 to enable the electronic device 10 to provide various functionalities.

In certain embodiments, the display 18 may be a liquid crystal display (LCD), which may allow users to view images generated on the electronic device 10. In some embodiments, the display 18 may include a touch screen, which may allow users to interact with a user interface of the electronic device 10. Furthermore, it should be appreciated that, in some embodiments, the display 18 may include one or more organic light emitting diode (OLED) displays, or some combination of LCD panels and OLED panels.

The input structures 22 of the electronic device 10 may enable a user to interact with the electronic device 10 (e.g., pressing a button to increase or decrease a volume level). The I/O interface 24 may enable electronic device 10 to interface with various other electronic devices, as may the network interface 26. The network interface 26 may include, for example, one or more interfaces for a personal area network (PAN), such as a Bluetooth network, for a local area network (LAN) or wireless local area network (WLAN), such as an 802.11x Wi-Fi network, and/or for a wide area network (WAN), such as a 3rd generation (3G) cellular network, 4th generation (4G) cellular network, Long-Term Evolution (LTE) cellular network, Long-Term Evolution license assisted access (LTE-LAA) cellular network, 5th generation (5G) cellular network, or New Radio (NR) cellular network,. The network interface 26 may also include one or more interfaces for, for example, broadband fixed wireless access networks (WiMAX), mobile broadband Wireless networks (mobile WiMAX), asynchronous digital subscriber lines (e.g., ADSL, VDSL), digital video broadcasting-terrestrial (DVB-T) and its extension DVB Handheld (DVB-H), ultra-wideband (UWB), alternating current (AC) power lines, and so forth. Network interfaces 26 such as the one described above may benefit from the use of tuning circuitry, impedance matching circuitry and/or noise filtering circuits that may include polymer capacitors such as the ones described herein. As further illustrated, the electronic device 10 may include a power source 28. The power source 28 may include any suitable source of power, such as a rechargeable lithium polymer (Li-poly) battery and/or an alternating current (AC) power converter.

In certain embodiments, the electronic device 10 may take the form of a computer, a portable electronic device, a wearable electronic device, or other type of electronic device. Such computers may include computers that are generally portable (such as laptop, notebook, and tablet computers) as well as computers that are generally used in one place (such as conventional desktop computers, workstations, and/or servers). In certain embodiments, the electronic device 10 in the form of a computer may be a model of a MacBook®, MacBook® Pro, MacBook Air®, iMac®, Mac® mini, or Mac Pro® available from Apple Inc. By way of example, the electronic device 10, taking the form of a notebook computer 10A, is illustrated in FIG. 2 in accordance with one embodiment of the present disclosure. The depicted computer 10A may include a housing or enclosure 36, a display 18, input structures 22, and ports of an I/O interface 24. In one embodiment, the input structures 22 (such as a keyboard and/or touchpad) may be used to interact with the computer 10A, such as to start, control, or operate a GUI or applications running on computer 10A. For example, a keyboard and/or touchpad may allow a user to navigate a user interface or application interface displayed on display 18.

FIG. 3 depicts a front view of a handheld device 10B, which represents one embodiment of the electronic device 10. The handheld device 10B may represent, for example, a portable phone, a media player, a personal data organizer, a handheld game platform, or any combination of such devices. By way of example, the handheld device 10B may be a model of an iPod® or iPhone® available from Apple Inc. of Cupertino, California. The handheld device 10B may include an enclosure 36 to protect interior components from physical damage and to shield them from electromagnetic interference. The enclosure 36 may surround the display 18. The I/O interfaces 24 may open through the enclosure 36 and may include, for example, an I/O port for a hard-wired connection for charging and/or content manipulation using a standard connector and protocol, such as the Lightning connector provided by Apple Inc., a universal serial bus (USB), or other similar connector and protocol.

User input structures 22, in combination with the display 18, may allow a user to control the handheld device 10B. For example, the input structures 22 may activate or deactivate the handheld device 10B, navigate user interface to a home screen, a user-configurable application screen, and/or activate a voice-recognition feature of the handheld device 10B. Other input structures 22 may provide volume control, or may toggle between vibrate and ring modes. The input structures 22 may also include a microphone may obtain a user's voice for various voice-related features, and a speaker may enable audio playback and/or certain phone capabilities. The input structures 22 may also include a headphone input may provide a connection to external speakers and/or headphones.

FIG. 4 depicts a front view of another handheld device 10C, which represents another embodiment of the electronic device 10. The handheld device 10C may represent, for example, a tablet computer, or one of various portable computing devices. By way of example, the handheld device 10C may be a tablet-sized embodiment of the electronic device 10, which may be, for example, a model of an iPad® available from Apple Inc. of Cupertino, California.

Turning to FIG. 5, a computer 10D may represent another embodiment of the electronic device 10 of FIG. 1. The computer 10D may be any computer, such as a desktop computer, a server, or a notebook computer, but may also be a standalone media player or video gaming machine. By way of example, the computer 10D may be an iMac®, a MacBook®, or other similar device by Apple Inc. It should be noted that the computer 10D may also represent a personal computer (PC) by another manufacturer. A similar enclosure 36 may be provided to protect and enclose internal components of the computer 10D such as the display 18. In certain embodiments, a user of the computer 10D may interact with the computer 10D using various peripheral input devices, such as the keyboard 22A or mouse 22B (e.g., input structures 22), which may connect to the computer 10D.

Similarly, FIG. 6 depicts a wearable electronic device 10E representing another embodiment of the electronic device 10 of FIG. 1 that may be configured to operate using the techniques described herein. By way of example, the wearable electronic device 10E, which may include a wristband 43, may be an Apple Watch® by Apple, Inc. However, in other embodiments, the wearable electronic device 10E may include any wearable electronic device such as, for example, a wearable exercise monitoring device (e.g., pedometer, accelerometer, heart rate monitor), or other device by another manufacturer. The display 18 of the wearable electronic device 10E may include a touch screen display 18 (e.g., LCD, OLED display, active-matrix organic light emitting diode (AMOLED) display, and so forth), as well as input structures 22, which may allow users to interact with a user interface of the wearable electronic device 10E.

In some embodiments, the electronic device 10 may include a system-on-a-chip (SOC) 50. For example, the SOC 50 may include an integrated circuit having the processor 12, the memory 14, the nonvolatile storage 16, the input structures 22, the input/output (I/O) interface 24, the network interface 26, and/or the power source 28, among other components. In any case, operations performed by the integrated circuit or die of the SOC (e.g., operations performed by the one or more processors 12) may generate heat, which may limit an operational capability (e.g., processing speed) of the SOC die. To maintain or increase operation capability of the SOC die, the SOC may include components that conduct heat (i.e., the heat generated based on the operations performed by the SOC die 54) away from the SOC die to the one or more thermal dissipation components (e.g., a heat sink, heat pipes, or the like).

FIG. 7 is a cross-sectional perspective view of the SOC 50. The illustrated embodiment of the SOC 50 includes a thermal management system 52 and an SOC die 54. The thermal management system 52 includes a thermal interface EMI shield 56, a heat spreader 58, a compression component 60, and one or more heat pipes 62. The thermal interface EMI shield 56 generally includes an EMI mesh 63 and a thermal interface material (TIM) 65, which, in some embodiments, may be integrated together. In some embodiments, the EMI mesh 63 may be in physical contact, and thus thermally couple to, the SOC die 54 and/or the heat spreader 58.

In general, the compression component 60 applies a downward force 64 that biases the one or more heat pipes 62 and the heat spreader 58 towards the thermal interface EMI shield 56, thereby thermally coupling the heat pipe 62 to the SOC die 54. More specifically, the downward force 64 may physically and thermally couple the heat spreader 58 to the thermal interface EMI shield 56. In some embodiments, clamps 67 may facilitate applying the downward force 64. Further, the pressure resulting from the downward force 64 applied by the heat spreader 58 may flatten or otherwise reduce a thickness of the TIM 65, thereby causing the TIM 65 to spread across the surface of the SOC die 54, the EMI mesh 63, the heat spreader 58, or both, as described in more detail with respect to FIG. 8. In any case, the downward force 64 applied by the heat spreader 58 may physically and thermally couple the thermal interface EMI shield 56 (e.g., the TIM 65 and/or the EMI mesh 63) to the SOC die 54. In this way, heat produced by the SOC die 54 may be transferred through the thermal interface EMI shield 56, and the heat spreader 58 thermally coupled to the thermal interface EMI shield 56, to be thermally dissipated via the one or more heat pipes 62. At least in some instances, the downward force 64 may help reduce or prevent air entrapment between the TIM 65 and the SOC die 54 and/or the TIM 65 and the heat spreader 58. That is, in certain SOC devices, there may be a risk of air entrapment when there is relative movement between the SOC die and a thermal module, such as when an electronic or computing device include the SOC die is subjected to shock and/or vibration. Accordingly, the downward force 64 applied by the heat spreader 58 may prevent such effects.

As generally described herein, it may be advantageous to include a thermal interface material (TIM) 65 between the SOC die 54 and the heat spreader 58 to facilitate thermal coupling between the SOC die 54 and the heat spreader 58. Further, it may be advantageous to provide EMI shielding to the SOC die 54. However, as adding additional materials or layers between the SOC die 54 and the heat spreader 58 may increase the thermal resistance. Accordingly, it is presently recognized that it may be advantageous to provide the disclosed thermal interface EMI shield 56 that reduces the amount of material (e.g., a thickness of layers) between the SOC die 54 and the heat spreader 58, while providing EMI shielding of the SOC die 54 and thermally coupling the SOC die 54 to the heat spreader 58.

To further illustrate this, FIG. 8 is a cross-sectional perspective view of the SOC 50 described with respect to FIG. 7. In general, the thermal interface EMI shield 56 includes an EMI mesh 63 having multiple windows 68 or recesses that form a mesh, webbed, or net structure along a top surface 70 of the SOC die 54 that may be physically coupled to the thermal interface EMI shield 56. In general, the EMI mesh 63 may be formed of a conductive material that forms an EMI shield (e.g., a Faraday cage) about at least a portion of the SOC die 54. Further, as previously described, the thermal interface EMI shield 56 includes a TIM 65.

As shown in the illustrated embodiment, the top surface 70 of the SOC die 54 is physically coupled to both the conductive material 66 and the TIM 65 layer. More specifically, and referring to the illustrated embodiment of FIG. 8, the TIM 65 layer extends through the windows 68, thereby forming a plurality of TIM channels 74. For example, the windows 68 and the TIM channels 74, together, form an alternating network of conductive material 66 and TIM 65. As such, both the TIM channels 74 and the conductive material 66 may be physically coupled to the top surface 70 of the SOC die 54 (e.g. when a sufficient downward force 64 is applied to the heat spreader 58).

However, in some embodiments the top surface 70 of the SOC die 54 may only be physically coupled to the TIM 65 layer. For example, the TIM 65 layer may be molded onto the conductive material 66 of the EMI mesh 63. In any case, a portion of the TIM 65 layer may permeate, extend, or otherwise traverse the window 68, such that when sufficient force 64 is applied to the heat spreader 58, the TIM 65 layer may be physically coupled (e.g. directly physically coupled) to the bottom surface 73 of the heat spreader and the top surface 70 of the SOC die 54.

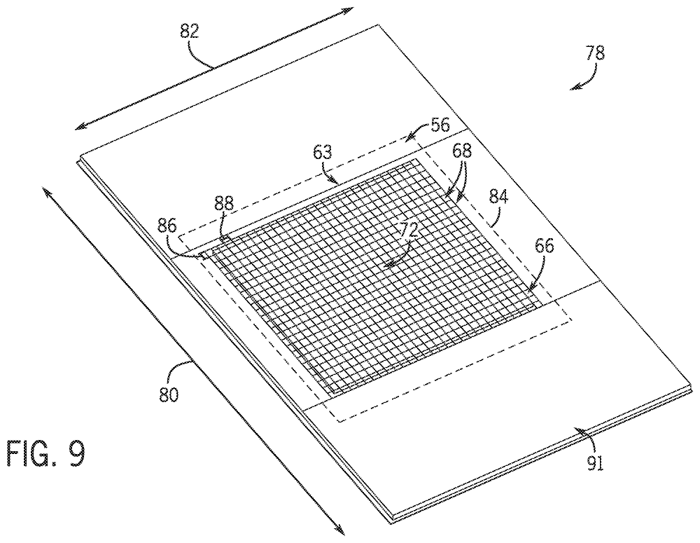

FIG. 9 is a perspective view of a lid 78 that includes the thermal interface EMI shield 56. In the illustrated embodiment, the thermal interface EMI shield 56 includes an EMI mesh 63. A surface 72 of the EMI mesh 63 includes the conductive material forming plurality of windows 68 arranged in an array 84. In the illustrated embodiment, the array 84 includes columns and/or rows. That is, the thermal interface EMI shield 56 includes multiple windows 68 disposed on different positions along a longitudinal axis 80 of the thermal interface EMI shield 56. Further, the thermal interface EMI shield 56 includes multiple windows 68 disposed on different positions along a transverse axis 82 of the thermal interface EMI shield 56. In general, the dimensions of the array 84 and/or the EMI mesh 63 may be sufficiently large such that the top surface 70 of the SOC die 54 may be covered by the array 84 when the SOC die 54 is attached to the thermal interface EMI shield 56. For example, the array 84 and/or the EMI mesh 63 may have a width and/length greater than 10 millimeters (mm), greater than 15 mm, greater than 20 mm, greater than 25 mm, or greater than 30 mm. In some embodiments, the dimensions of the array 84 may be relatively larger than the dimensions of the top surface 70. For example, the dimensions of the array 84 may be 10%, 20%, 30%, 40, 50%, or greater than 50% larger than the dimensions of the top surface 70. In additional or alternative embodiments, the dimensions of the array 84 may be relatively smaller than the dimensions of the top surface 70. For example, the dimensions of the array 84 may be 10%, 20%, 30%, 40, 50%, or greater than 50% smaller than the dimensions of the top surface 70.

The dimensions of the windows 68 may be of a suitable size to provide electromagnetic interference shielding about at least a portion of the SOC die 54. Further, the dimensions of the windows 68 may permit the TIM 65 layer to permeate, extend, or otherwise traverse in the presence of the pressure resulting from the force 64. For example, a width 86 and/or a length 88 of the windows 68 may be 0.25 mm or less, 0.5 mm or less, 0.75 mm or less, 1 mm or less, 2 mm or less, 5 mm or less, and so on. Although the illustrated embodiment of FIG. 9 shows the width 86 to be substantially equal to the length 88, it should be noted that at least in some instances one or more of the window 68 within the array 84 may have different widths 86 and or lengths 88. For example, a first portion of the window 68 may have a first width and a first length, and a second portion of the window 68 may have a second width and a second length that are different than the first with the first length. Moreover, the thermal interface EMI shield 56 may have a thickness 91 suitable for permitting TIM 65 layer to permeate extend or otherwise traverse in the presence of the pressure resulting from the force 64. For example, the thickness 91 may be 5 mm or less, 2 mm or less, 1 mm or less, 0.75 mm or less, 0.5 mm or less, 0.25 mm or less, and so on.

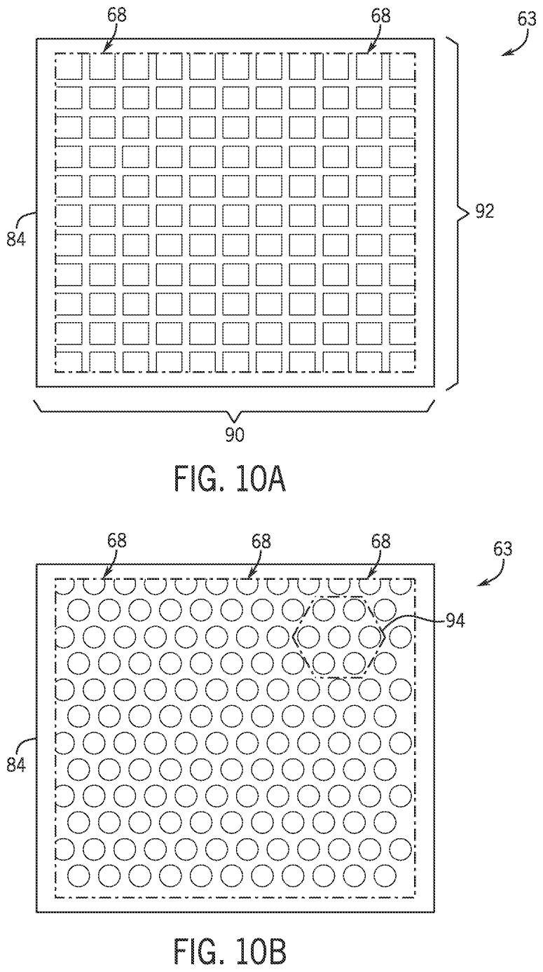

To further illustrate examples of the thermal interface EMI shield 56, FIGS. 10A and 10B show perspective views of two examples of the EMI mesh 63. FIG. 10A shows an example of an EMI mesh 63 having an array 84 of square or rectangular shaped windows 68. In the illustrated embodiment, the windows 68 are arranged in columns 90 and rows 92. While the illustrated embodiment shows the rows 92 and columns 90 in a regular and/or matrix organization pattern, it should be noted that the row 92 and columns 90 may also be arranged in an irregular, staggered pattern. FIG. 10B shows an example of an EMI mesh 63 having an array 84 of circular or oval-shaped windows 68 and arranged in a staggered, honey-comb pattern 94. Although the shape of the windows 68 in FIGS. 10A and 10B are illustrated as being substantially uniform (e.g. having the same shape), it should be noted that in some embodiments the windows 68 may include different shapes. For example, the EMI mesh 63 may include a first portion of windows 68 having a circular shape, and the EMI mesh 63 may include a second portion of window 68 having a rectangular shape. It should be noted that the square and circle shapes of the windows 68 are only examples of the shapes of the windows 68. That is, it should be noted than any other shape that promotes EMI shielding may be used (e.g., rectangles, hexagons, octagons, pentagons, and so on).

As described above, the sizes of the windows 68 may vary at different positions within the array 84. For example, the dimensions of the windows 68 at the center of the EMI mesh 63 may be relatively larger than the windows 68 near or at the ends of the array 84. Alternatively, the dimensions of the windows 68 at the center of the EMI mesh 63 may be relatively smaller than the windows 68 near or at the ends of the array 84.

In some embodiments, the spacing between windows 68 or amount of conductive material 66 may vary at different positions within the array 84. For example, the spacing between the windows 68 at the center of the EMI mesh 63 may be relatively larger than the windows 68 near or at the ends of the array 84. Alternatively, the spacing between the windows 68 at the center of the EMI mesh 63 may be relatively smaller than the windows 68 near or at the ends of the array 84. It should be noted that increasing the spacing may increase the mechanical stiffness of the EMI mesh 63 while decreasing the spacing may decrease the mechanical stiffness of the EMI mesh 63. Accordingly, it may be advantageous to tune the spacing based on the amount of pressure provided by or to be provided by the heat spreader 58.

At least in some instances, the presence of the windows 68 in the EMI mesh 63 may reduce the mechanical stiffness of the conductive along the top surface 70 of the SOC die 54 and/or the bottom surface 76 of the heat spreader 58. As such, it may be desirable to increase the mechanical stiffness of the EMI mesh 63 by employing reinforcing structures (e.g., rods, ribs, grills), embossment, and the like, across the EMI mesh 63 and/or the thermal interface EMI shield 56.

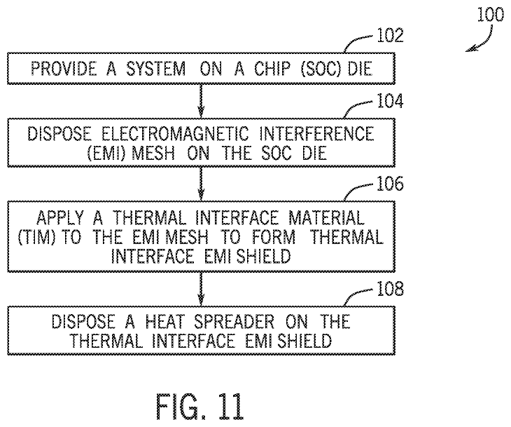

FIG. 11 is a flowchart of a method 100 for manufacturing the thermal interface EMI shield 56. While the method 100 is described using steps in a specific sequence, it should be understood that the present disclosure contemplates that the described steps may be performed in different sequences than the sequence illustrated, and certain described steps may be skipped or not performed altogether. For example, in some embodiments, block 104 may be performed before block 102. In some embodiments, the method 100 may be performed with block 106 omitted.

In process block 102, a SOC die 54 is provided. For example, the SOC die 54 may be a die disposed on a main logic board of an electronic device. In process block 104, the EMI mesh 63 is disposed on the SOC die 54. For example, the EMI mesh 63 may be applied to or otherwise placed on the top surface 70 of the SOC die 54. In block 106, the TIM 65 is applied to the EMI mesh 63, thereby providing the thermal interface EMI shield 56 to the SOC die 54. In some embodiments, providing the thermal interface EMI shield 56 may include providing a TIM 65 layer and the EMI mesh 63 separately. For example, the EMI mesh 63 may be provided to or coupled to the top surface 70 of the SOC die 54. Then, the TIM 65 layer may be deposited, applied, or otherwise provided onto a surface of the EMI mesh 63, thereby forming a thermal interface EMI shield 56 where the EMI mesh 63 is an intervening layer between the TIM 65 layer and the SOC die 54. In some embodiments, the TIM 65 layer may have a relatively low viscosity such that the TIM 65 layer may permeate, extend, or otherwise traverse the windows 68 of the EMI mesh 63 without the presence of the pressure resulting from the force 64. In such embodiments, the SOC die 54 may directly physically contact both the EMI mesh 63 and the TIM 65 layer.

However, in some embodiments, the TIM 65 layer may have a relatively high viscosity such that the TIM 65 layer may permeate, extend, or otherwise traverse the windows 68 of the EMI mesh 63 in the presence of the pressure resulting from the force 64. In such embodiments, the SOC die 54 may directly contact the EMI mesh 63 while not directly contacting the TIM 65 layer.

Furthermore, in some embodiments, the TIM 65 layer may be provided to or coupled to the top surface 70 of the SOC die 54 prior to the applying the EMI shield. Accordingly, the SOC die 54 may directly contact the TIM 65 layer while not directly contacting the EMI mesh 63. In some embodiments, the TIM 65 layer and the EMI mesh 63 may be provided as an integrated component. For example, the TIM 65 layer may be molded or otherwise affixed or attached to the EMI mesh 63(e.g., including in the windows 68 of the EMI mesh 63). The integrated TIM 65 layer and EMI mesh 63 may then be provided to the SOC die 54 together (e.g., in a single step). At least in some instances, attaching the TIM 65 layer and the EMI mesh 63 may cause a portion of the TIM 65 layer to permeate, extend, or otherwise traverse the windows 68 of the EMI mesh 63.

In process block 108, the heat spreader 58 is disposed on, applied to, or otherwise coupled to the thermal interface EMI shield 56. In general, the heat spreader 58 may be provided to contact a surface of the thermal interface EMI shield 56 that is opposite of the SOC die 54, thereby enabling thermal coupling between the heat spreader 58 and the thermal interface EMI shield 56. In some embodiments, the heat spreader 58 may directly contact (e.g., physically couple to) the TIM 65 layer, the EMI mesh 63, or both. At least in some instances, providing the heat spreader 58 to the thermal interface EMI shield 56 may provide a pressure to the TIM 65 layer, thereby causing the TIM material to permeate, extend, or otherwise traverse the windows 68 of the EMI mesh 63.

It is well understood that the use of personally identifiable information should follow privacy policies and practices that are generally recognized as meeting or exceeding industry or governmental requirements for maintaining the privacy of users. In particular, personally identifiable information data should be managed and handled so as to minimize risks of unintentional or unauthorized access or use, and the nature of authorized use should be clearly indicated to users.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

What is claimed is:

1. An electronic device, comprising:
a semiconductor die;
a thermal interface material (TIM) thermally coupled to a surface of the semiconductor die; and
a shielding lid thermally coupled to the semiconductor die along the surface of the semiconductor die.

2. The electronic device of claim 1, wherein the shielding lid comprises an array of windows along width and length of the shield lid.

3. The electronic device of claim 2, wherein the TIM is at least partially disposed within the array of windows of the shielding lid.

4. The electronic device of claim 1, wherein the shielding lid is physically coupled to the surface of the semiconductor die.

5. The electronic device of claim 1, comprising a spreader physically coupled to the TIM.

6. The electronic device of claim 1, wherein the shielding lid comprises a conductive material.

7. The electronic device of claim 1, wherein the TIM comprises a phase change material, a thermal paste, a thermal adhesive, or any combination thereof.

8. A thermal electromagnetic interference (EMI) shield, comprising:
an EMI mesh comprising a conductive material forming a plurality of windows; and
a thermal interface material (TIM) coupled to the conductive material.

9. The thermal EMI shield of claim 8, wherein at least a portion of the TIM is disposed between the windows.

10. The thermal EMI shield of claim 8, wherein a length or width of each window of the plurality of windows is 1 millimeter or less.

11. The thermal EMI shield of claim 8, wherein a portion of the TIM is disposed within the plurality of windows.

12. The thermal EMI shield of claim 8, wherein the EMI mesh comprises a surface, and wherein the surface comprises the conductive material forming plurality of windows arranged in columns or rows.

13. The thermal EMI shield of claim 8, wherein the EMI mesh comprises a dimension that is 30 mm or less.

14. The thermal EMI shield of claim 8, wherein the TIM is configured to physically couple to a die.

15. A thermal management system, comprising:
a thermal electromagnetic interference (EMI) shield comprising:
a thermal interface material (TIM); and
an EMI mesh thermally coupled to the TIM, wherein the EMI mesh comprises a plurality of windows, and wherein a portion of the TIM is disposed between the plurality of windows; and
a heat spreader physically coupled to the TIM.

16. The thermal management system of claim 15, comprising a compression component configured to bias the heat spreader towards the EMI mesh.

17. The thermal management system of claim 15, comprising one or more heat pipes coupled to the heat spreader.

18. The thermal management system of claim 15, wherein a thickness of the EMI shield is 1 millimeter or less.

19. The thermal management system of claim 15, wherein a length, a width, or both, of the plurality of the windows are substantially the same.

20. The thermal management system of claim 15, wherein a shape of the plurality of the windows is substantially the same.
